(19) United States
(12) Patent Application Publication
(10) Pub. No.: US 2003/0231053 A1
(43) Pub. Date: Dec. 18, 2003

(54) Tunable filter circuit including a phase locked loop

(75) Inventor: Jae-Hwan Kim, Suwon-shi (KR)

Correspondence Address: Paul J. Farrell, Esq., DILWORTH & BARRESE, LLP, 333 Earle Ovington Blvd., Uniondale, NY, 11553, US

(73) Assignee: SAMSUNG THALES CO., LTD., Kyongsangbuk-Do (KR)

(21) Appl. No.: 10/282,371

(22) Filed: Oct. 29, 2002

(30) Foreign Application Priority Data
Jun. 14, 2002 (KR) 2002-33228

(51) Int. Cl. H03B 1/00

(52) U.S. Cl. 327/552

(57) ABSTRACT

A tunable filter circuit using a phase locked loop for filtering signals by varying a center frequency of the tunable filter circuit. The tunable filter circuit includes a phase locked loop and a resonance circuit. The phase locked loop includes: a voltage controlled oscillator having a resonance circuit, of which center frequency is varied in correspondence to an inputted control voltage level, for oscillating a frequency signal corresponding to the inputted control voltage level; a PPL controller for generating an error voltage signal corresponding to a phase difference by comparing a reference frequency signal to a signal phase that is oscillated by the voltage controlled oscillator, in correspondence to frequency control data for variably setting a resonance frequency of the voltage controlled oscillator; and a loop filter for loop filtering the error voltage signal and for outputting the loop filtered signal to the voltage controlled oscillator as the control voltage. The resonance circuit has the identical oscillation characteristic with the resonance circuit of the voltage controlled oscillator, and filters and then outputs signals from a wanted frequency band appropriate for a center frequency that varies in accordance with the control voltage level to an inputted signal.

### PRIORITY

This application claims priority to an application entitled “Tunable Filter Circuit Using the Phase Locked Loop” filed in the Korean Industrial Property Office on Jun. 14, 2002 and assigned Serial No. 2002-33228, the contents of which are hereby incorporated by reference.

### BACKGROUND OF THE INVENTION

1. Field of the Invention

The present invention relates generally to tunable filter circuits, and more particularly, to a tunable filter circuit including a phase locked loop for filtering and outputting inputted signals.

2. Description of the Related Art

Conventionally, multi-channel communication systems selectively receive desired frequency signals. Typically, a circuit used for selective reception is a tunable filter circuit that receives frequency signals of full range, and then filters the signals of a desired frequency band. In general, a capacity of a coil inductor or capacitor in the tunable filter circuit varies depending on a voltage applied; so more current flows in a specific frequency. Therefore, tuning in different frequencies can be accomplished through different variations or combinations of such inductors or capacitors. Here, tuning involves placing a tunable circuit in an input circuit, and changing a capacity of a capacitor or induction coefficient of an inductor to set a resonant frequency of the tunable circuit at a desired frequency. In other words, the tunable filter circuit passes only specific frequency signals or a frequency band, and does not pass (filters out) other frequency signals that are not selected or desired.

Therefore, to receive a certain frequency signal, a center frequency of the tunable filter circuit in a system must be varied in accordance with a desired frequency band signal. To vary the center frequency of the tunable filter circuit, a resonance circuit's element values are switched or combined.

FIG. 1 is a schematic circuit diagram of a conventional tunable filter, in which each element value of the filter is switched and combined to vary the center frequency. As illustrated in FIG. 1, a tunable filter circuit 100 includes a resonance circuit 110 and a switching circuit 120. Switching circuit 120 receives a control signal 130. The control signal 130 is for switching the switching circuit 120 that varies the center frequency of the tunable filter circuit. By this switching, a ground voltage is connected to elements of the resonance circuit 110.

In resonance circuit 110 connected by switching, a maximum amount of current flows at a specific frequency of the power supply. Usually, the frequency varies depending on either the shape of a circuit, the inductor value, or the capacitor value. Taking advantage of this feature, it is possible to capture an output characteristic of a desired frequency. Thus, the resonance circuit 110 receives a signal input 151, and after filtering the signal input 151, performs signal output 152.

To summarize, the tunable filter circuit 100 in the related art performed switching in the switching circuit 120 in response to the control signal 130, and by combining element values of the resonance circuit 110, varies the center frequency thereof. Therefore, the conventional tunable filter circuit 100 includes a switching circuit 120, and a resonance circuit 110 composed of a plurality of elements. Consequently, a number of elements are also necessary for applying the tunable filter circuit 100 to a system. Naturally, the tunable filter circuit 100 itself is very big because of many elements mounted therein. Another drawback is high power consumption, because it is necessary to input a switching control signal 130 corresponding to a center frequency to be varied in order to change or set the center frequency in the switching circuit 120. Moreover, the control operation following the switching to vary the center frequency is very complicated and in performing this complicated process, a large amount of time is wasted.

As described above, variation of a center frequency of a known tunable filter circuit is realized by combining element values of an oscillation filter 100. In doing so, however, the tunable filter circuit 100 including a switching circuit 120 and a resonance circuit 110 requires a separate element, and as a result thereof, the size of the circuit had to be big. In addition, the tunable filter circuit 100 in the related art is disadvantageous in terms of power consumption because a switching control signal must be input in the switching circuit 120 every time the center frequency is varied. Besides, the procedure involved in inputting the switching control signal and switching to vary the center frequencies is very complicated and requires a large amount of time to perform.

### SUMMARY OF THE INVENTION

It is, therefore, an object of the present invention to provide a tunable filter circuit including a reduced number of elements and a reduced size.

Another object of the present invention is to provide a tunable filter circuit, which is capable of reducing power consumption necessary for varying a center frequency of the circuit.

Still another object of the present invention is to provide a tunable filter circuit including a simple control procedure for varying a center frequency of the circuit.

To achieve the above objects, there is provided a tunable filter circuit, including: a Phase Locked Loop (PLL), which includes a voltage controlled oscillator having a resonance circuit, of which a center frequency is varied in response to an input control voltage level, for oscillating a frequency signal corresponding to the inputted control voltage level, a PPL controller for generating an error voltage signal corresponding to a phase difference by comparing a reference frequency signal to a signal phase that is oscillated by the voltage controlled oscillator, corresponding to frequency control data for variably setting a resonance frequency of the voltage controlled oscillator, and a loop filter for loop filtering the error voltage signal and for outputting the loop filtered signal to the voltage controlled oscillator as the control voltage; and a resonance circuit, which has an identical oscillation characteristic as the resonance circuit of the voltage controlled oscillator, for filtering and outputting signals from a desired frequency band for a center frequency that varies in accordance with the control voltage level to an input signal.

### BRIEF DESCRIPTION OF THE DRAWINGS

The above and other objects, features, and advantages of the present invention will become more apparent from the following detailed description when taken in conjunction with the accompanying drawings in which:

FIG. 1 is a schematic diagram of a conventional tunable filter circuit;

FIG. 2 is a schematic diagram of a tunable filter circuit using a Phase Locked Loop according to a preferred embodiment of the present invention;

FIG. 3 is a schematic diagram of a tunable filter circuit according to the preferred embodiment of the present invention;

FIG. 4 illustrates a frequency output of a conventional Phase Locked Loop; and

FIG. 5 illustrates an output of a tunable filter circuit including a phase locked loop according to a preferred embodiment of the present invention.

### DETAILED DESCRIPTION OF THE PREFERRED EMBODIMENT

A preferred embodiment of the present invention will be described herein below with reference to the accompanying drawings. In the following description, well-known functions or constructions are not described in detail since they would obscure the invention in unnecessary detail.

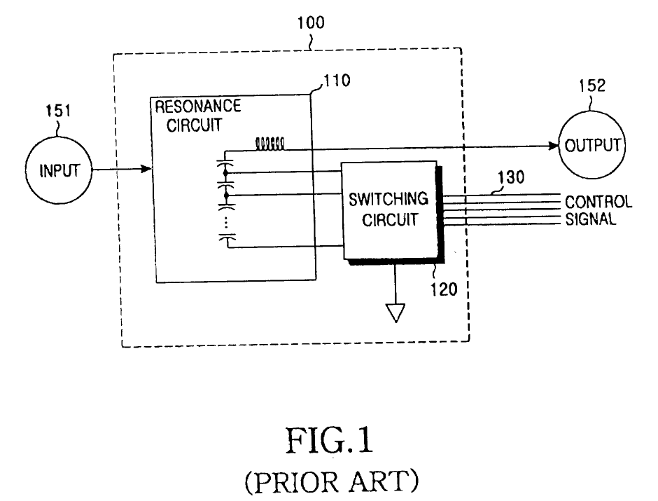

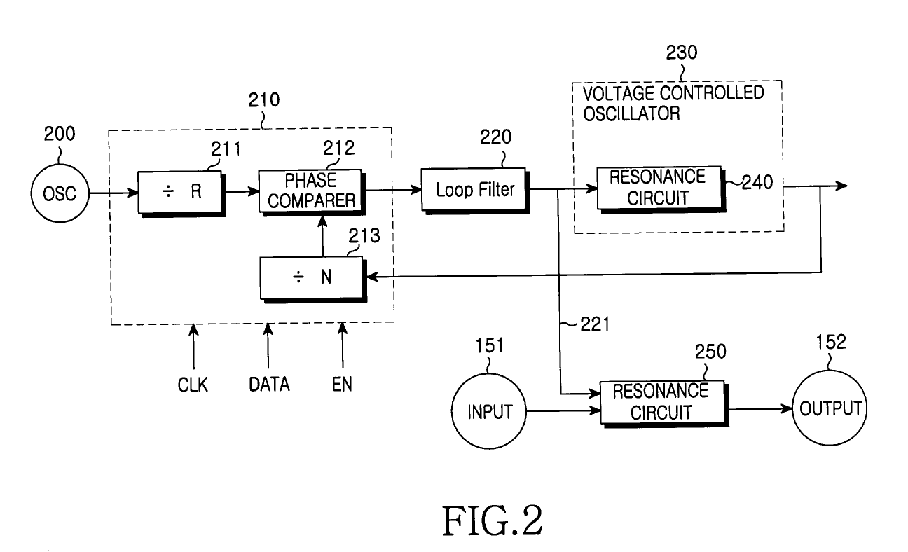

FIG. 2 is a diagram of a tunable filter circuit using a Phase Locked Loop (PLL) in accordance with a preferred embodiment of the present invention. Unlike the tunable filter circuit illustrated in FIG. 1, wherein resonance circuit element values are switched and combined to vary a center frequency, the tunable filter circuit of the present invention uses a general PLL that is fabricated and sold as one chip (IC) in the market.

A typical PLL includes a phase locked loop controller 210, a loop filter 220, and a voltage controlled oscillator 230. The phase locked loop controller 210 is a general PLL frequency synthesizing IC, and generates voltage for applying to the voltage controlled oscillator 230. In addition, the phase locked loop controller 210 includes a reference frequency divider 211, a phase comparator 212, and a programmable divider 213.

Reference frequency divider 211 receives a resonance frequency signal from the oscillator (OSC) 200, and outputs a reference frequency to the phase comparator 212. Mostly, the reference frequencies used in the phase comparator 212 are channel space frequencies, but the frequency values belong to low frequencies out of a transmission band. However, considering that a crystal oscillator is most commonly used for the phase locked loop, low frequencies for use of the reference frequency are pretty difficult to obtain. To avoid such a problem, a frequency generated by the oscillator 200 is set very high, and the reference frequency divider 211 outputs a reference frequency by dividing the high frequency.

The phase comparator 212 compares a phase of the reference frequency outputted from the reference frequency divider 211 to a phase of the comparison frequency outputted from the programmable divider 213. Here, the programmable divider 213, based on frequency signals that are outputted from voltage controlled oscillator 230, changes program N (integral number), and further, a dividing ratio. If the phase locked loop is locked, the reference frequency and the comparison frequency are same.

In other words, by altering the program N (integral number) value of the programmable divider 213, a more accurate integer ratio of the reference frequency can be output from the voltage controlled oscillator 230. At this time, the program N (integral number) is changed depending on frequency control data.

As described above, the phase comparator 212 compares a phase of the reference frequency generated by the reference frequency divider 211 to a phase of the comparison reference generated by the programmable divider 213, and outputs an error voltage signal corresponding to the phase difference to the loop filter 220.

After receiving the error voltage signal, the loop filter 220 integrates the error voltage signal, and outputs the result as a direct current control voltage to the resonance circuit 240 of the voltage controlled oscillator 230, and to the resonance circuit 250 of the tunable filter circuit.

The voltage controlled oscillator 230 outputs a frequency signal corresponding to a control voltage that is input via the loop filter 220. The resonance circuit 240 in the voltage controlled oscillator 230 is provided with the control voltage, and as a result, a maximum amount of current flows in a specific frequency. By changing the voltage of a variable capacity diode in the resonance circuit 240, the frequency can also be changed or generated. Further, the resonance circuit 240 has a band pass filtering characteristic. The output signal generated at the voltage controlled oscillator 230 is fed back to the comparison frequency divider 213 in the phase locked loop controller 210. Then, the phase comparator 212 compares the comparison frequency from the comparison frequency divider 213 to the reference frequency, and generates a control voltage corresponding to the phase difference.

As described above, the phase comparator 212 generates an output voltage or current corresponding to the phase difference between two signals. The output of the phase comparator 212 is feed backed to the voltage controlled oscillator 230 to tune the voltage control oscillator 230 to a desirable frequency. In this manner, the output signal of the voltage controlled oscillator 230 has the same frequency as the reference frequency signal. In addition, the reference frequency is compared to the program integer ratio (N) divided output frequency of the voltage controlled oscillator 230, and then the output of the voltage controlled oscillator 230 is tuned to the N times of the reference frequency. Therefore, the output frequency of the voltage controlled oscillator 230 can be varied by changing the program N (integral number) value of the programmable divider 213.

The operation involved in the variation and setting the center frequency of the tunable filter circuit using the phase locked loop whose output frequency varies in accordance with the N value of the programmable divider 213 will be described herein below.

First, the resonance circuit 240 inside of the voltage controlled oscillator 230 is designed in such manner that it outputs frequency signals the tunable filter circuit wants. Also, the tunable filter circuit is configured with the same element values as those of the resonance circuit 240 in the voltage controlled oscillator 230. By adjusting quality factor of the tunable filter circuit, a desired filter is obtained.

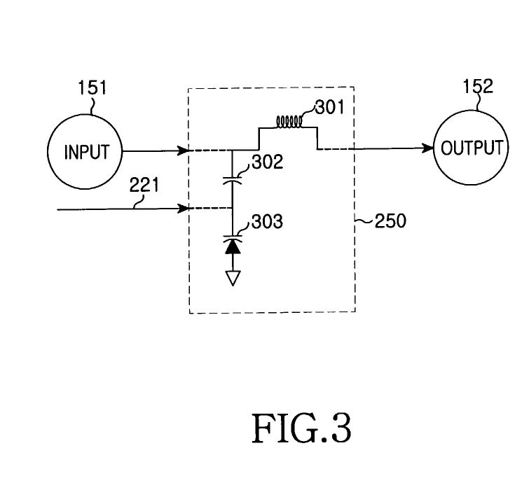

FIG. 3 illustrates a resonance circuit 250 as the tunable filter circuit. The reference numeral 221 indicates a control voltage that is output from loop filter 220. The tunable filter circuit 250 includes an earthed variable capacity diode 303, an inductor 301, and capacitor 302, which is disposed between the variable capacity diode 303 and inductor the 301, in series. The inductor 301 is connected between input 151 and output 152. The resonance frequency output from the resonance circuit 250 is influenced by inductor 301, capacitor 302, and a capacitance value of variable capacity diode 303.

In short, the frequency is changed by adjusting capacitance value of variable capacity diode 303 of a tunable filter circuit 250 that has the same configuration with the resonance circuit 240 of the phase locked loop.

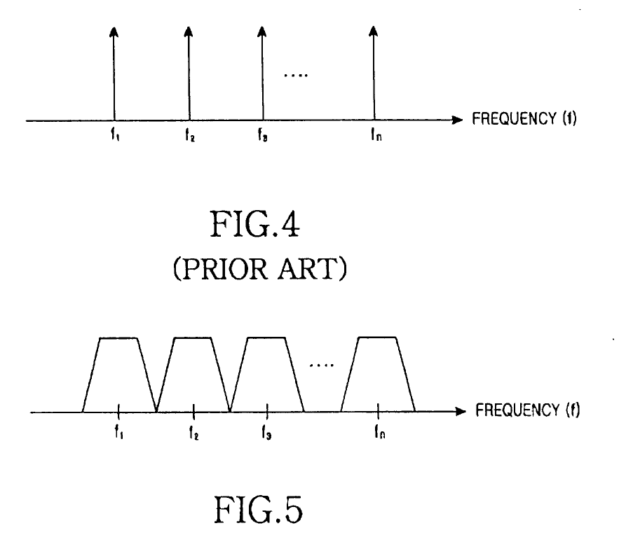

FIG. 4 illustrates a frequency output of a conventional phase locked loop, and FIG. 5 illustrates an output of a tunable filter circuit including a phase locked loop embodying principles of the present invention.

For example, in FIG. 4, suppose that the output frequency of the phase locked loop is f1. Then, the output center frequency of the tunable filter circuit is also f1. That is, when the frequency of the phase locked loop is changed, the center frequency of the tunable filter circuit 250 can be varied by changing capacitance of the variable capacity diode 303 inside of the circuit, using the voltage that passed through the loop filter 220.

The tunable filter circuit of the present invention has the identical configuration and element values with those of the resonance circuit 240 inside of the voltage controlled oscillator 230, and the center frequency of the tunable filter circuit is changed every time the frequency of the phase locked loop is changed. Also, since the voltage inputted into the resonance circuit 240 is fixed by the phase locked loop, it is not drifted at all. Thus, it is possible to set or change the center frequency of the tunable filter circuit stably.

To summarize, the same frequency as the center frequency the tunable filter circuit intends to design should be outputted as the output frequency of the phase locked loop.

As described above, similar to the resonance circuit inside of the voltage controlled oscillator 230, a tunable filter circuit using the resonance circuit inside of the voltage controlled oscillator 230 can be designed without using a separate tunable filter circuit. However, to utilize the resonance circuit inside of the voltage controlled oscillator 230, a matching circuit is required on the both ends of the resonance circuit.

In conclusion, the present invention has attractive features like small size, simple control procedure, and low power consumption. More specifically, when a center frequency of the tunable filter circuit needs to be varied, instead of using a resonance circuit including a switching circuit and a number of individual elements, the present invention uses a phase locked loop (PLL) as a component of the tunable filter circuit. This consequently reduces the number of elements used in the circuit and the size of the circuit. Also, simply by changing a program N (integral number) value of the programmable divider of the phase locked loop in accordance with the center frequency to be varied, it is easy to make the output frequency of the phase locked loop match the center frequency of the tunable filter circuit. This simple control procedure does not take much time and the power consumption thereof is also very low.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A tunable filter circuit, comprising:
a Phase Locked Loop (PLL), which includes a voltage controlled oscillator having a resonance circuit, of which a center frequency is varied in correspondence to an input control voltage level, for oscillating a frequency signal corresponding to the input control voltage level; a PPL controller for generating an error voltage signal corresponding to a phase difference by comparing a reference frequency signal to a signal phase that is oscillated by the voltage controlled oscillator, corresponding to frequency control data for variably setting a resonance frequency of the voltage controlled oscillator; and a loop filter for loop filtering the error voltage signal and for outputting the loop filtered signal to the voltage controlled oscillator as the control voltage; and
a resonance circuit, which has an identical oscillation characteristic as the resonance circuit of the voltage controlled oscillator, for filtering and outputting signals from a desired frequency band for a center frequency that varies in accordance with the control voltage level to an input signal.

2. The tunable filter circuit as claimed in claim 1, wherein the resonance circuit has identical elements as the resonance circuit included in the voltage controlled oscillator of the phase locked loop.
